(19) United States
(12) Patent Application Publication
(10) Pub. No.: US 2015/0034280 A1
(43) Pub. Date: Feb. 5, 2015

(54) HEADER FOR ELECTRONIC COOLER

(71) Applicant: Hamilton Sundstrand Corporation, Charlotte, NC (US)

(72) Inventors: Richard A. Himmelmann, Beloit, WI (US); Joseph Turney, Amston, CT (US)

(73) Assignee: Hamilton Sundstrand Corporation, Charlotte, NC (US)

(21) Appl. No.: 13/956,420

(22) Filed: Aug. 1, 2013

(51) Int. Cl. H05K 1/02; H05K 7/20; F28D 15/00

(52) U.S. Cl. CPC H05K 1/0203; F28D 15/00; H05K 7/20009; H05K 7/20218
USPC 165/104.33

(57) ABSTRACT

A fluid cooler packet for a plurality of electronic components has a plurality of individual cooling circuits for receiving a supply of cooling fluid from a supply header and delivering that cooling fluid to an associated electronic component. The plurality of cooling circuits each includes a return passage for receiving a return fluid after having cooled the associated electronic component, and returns the return fluid to a return header. A volume of the supply header decreases in a downstream direction as it passes over the plurality of individual cooling circuits. A volume of the return header increases as it moves in a downstream direction over the plurality of individual cooling circuits. An electronic component array is also disclosed.

### BACKGROUND

This application relates to a header for supplying cooling fluid to electronic components and for returning the cooling fluid.

Electronics are becoming utilized in more and more applications. The size of the electronic components is continuously being reduced. There are now any number of electronic chips that are sized one millimeter by one millimeter, and even smaller.

As the applications controlled and performed by the electronics have increased, the heat generated by the electronics has also increased. The historic ways of dissipating heat, such as heat fins, may no longer always be adequate. Thus, it becomes important to provide cooling fluid in an efficient manner to the very small electronic components.

In addition, the electronics are being packed in plural arrays. The cooling fluid must be provided to the several electronics components in an efficient manner.

### SUMMARY

A fluid cooler packet for a plurality of electronic components has a plurality of individual cooling circuits for receiving a supply of cooling fluid from a supply header and delivering that cooling fluid to an associated electronic component. The plurality of cooling circuits each includes a return passage for receiving a return fluid after having cooled the associated electronic component, and returns the return fluid to a return header. A volume of the supply header decreases in a downstream direction as it passes over the plurality of individual cooling circuits. A volume of the return header increases as it moves in a downstream direction over the plurality of individual cooling circuits. An electronic component array is also disclosed.

These and other features may be best understood from the following drawings and specification.

### BRIEF DESCRIPTION OF THE DRAWINGS

FIG. 1 shows an electronic component.

FIG. 2A shows an array including a plurality of the FIG. 1 components.

FIG. 2B shows a cooling circuit for cooling one of the electronic components within the array of FIG. 2A.

FIG. 2C shows a detail of one layer.

FIG. 2D shows a detail of another layer.

FIG. 2E shows a sandwich assembly of layers shown in FIG. 2B.

FIG. 3A shows the overall flow passage associated with one cooling circuit.

FIG. 3B shows a portion of the flow path.

FIG. 3C shows another portion of the flow path.

FIG. 4 shows a header for communicating all of the separate cooling circuits together.

FIG. 5A shows an alternative header.

FIG. 5B shows a detail of the FIG. 5A header.

FIG. 5C shows a benefit of the FIG. 5A header.

FIG. 5D shows another embodiment.

### DETAILED DESCRIPTION

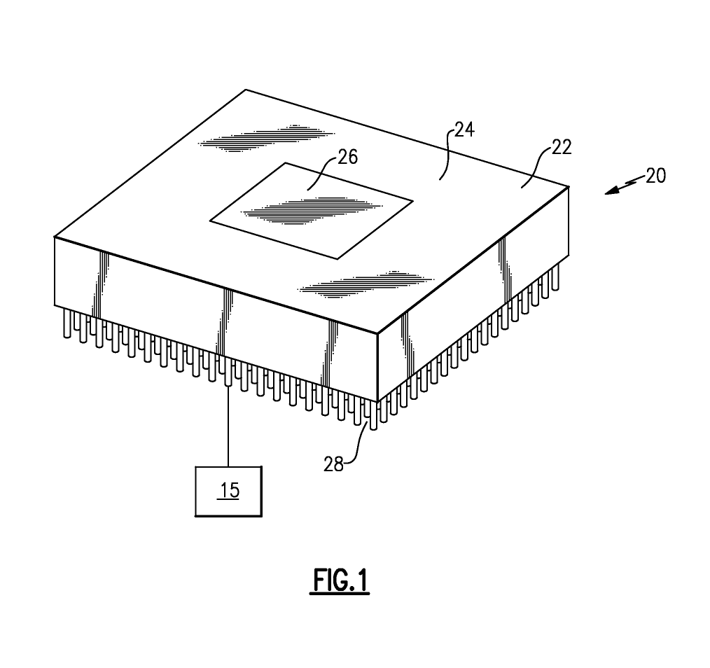

FIG. 1 shows an electronic assembly 20. The assembly includes an electronic component 22 that may be extremely small and on the order of one millimeter by one millimeter as an example. Of course, this size is merely an example.

The electronic component 22 may be a computer chip or other electronic element. The component is shown schematically controlling a system 15. The electronic component 22 is shown schematically connected to system 15 by connector pins 28. An area 26 may generate more heat than an area 24.

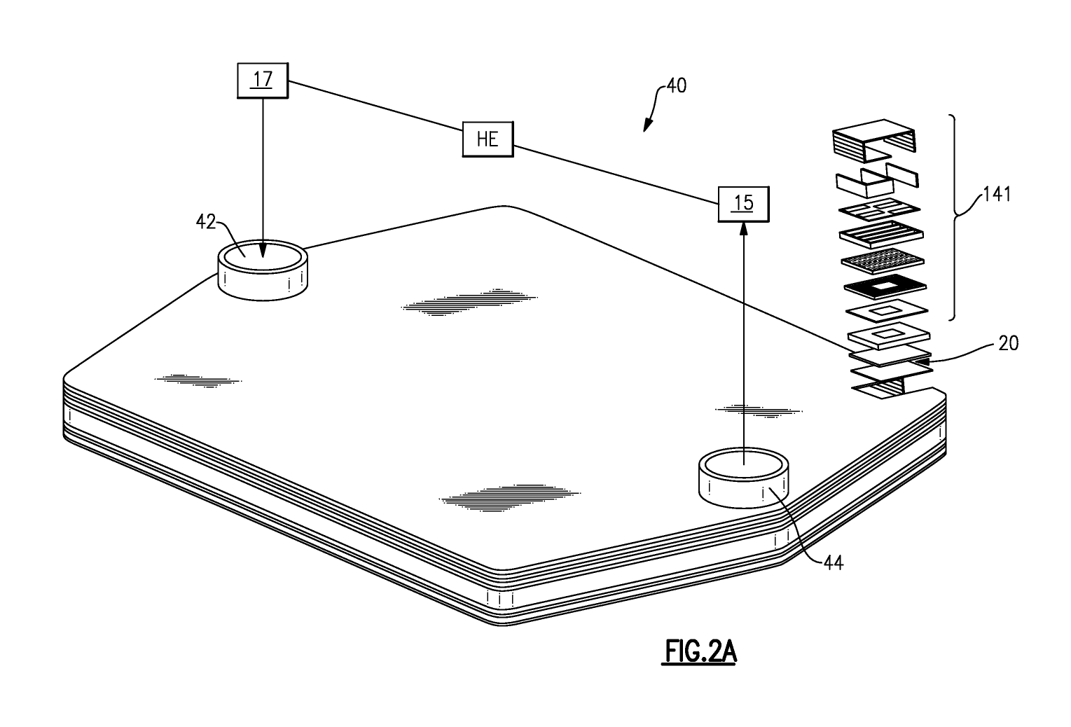

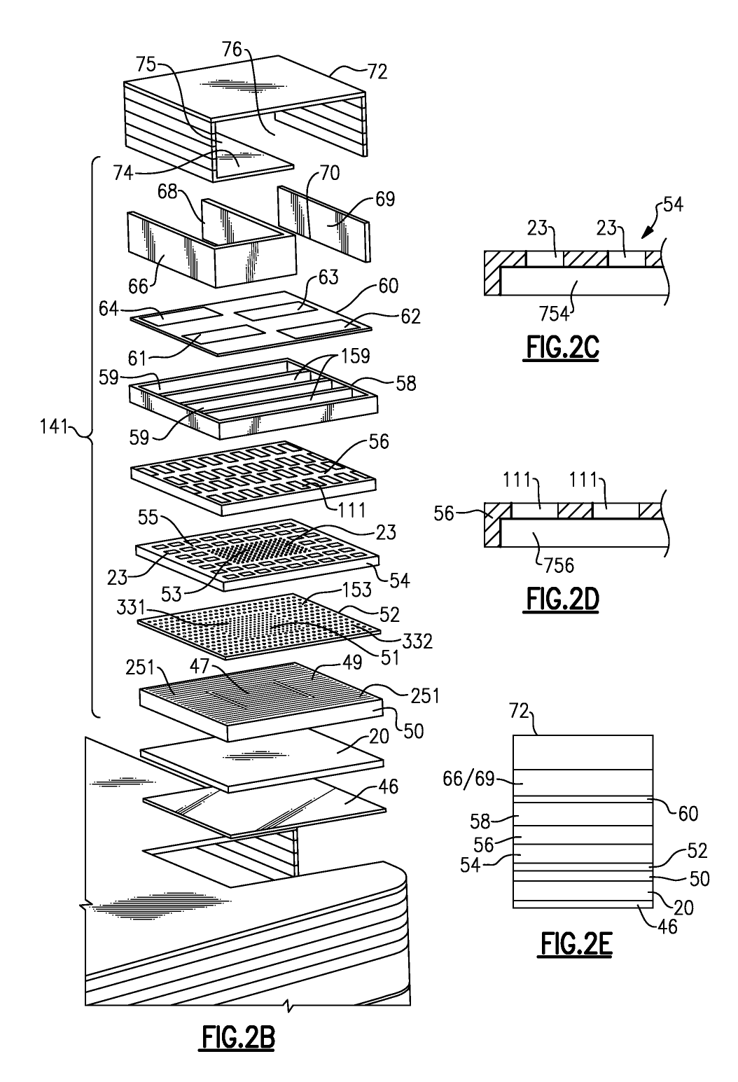

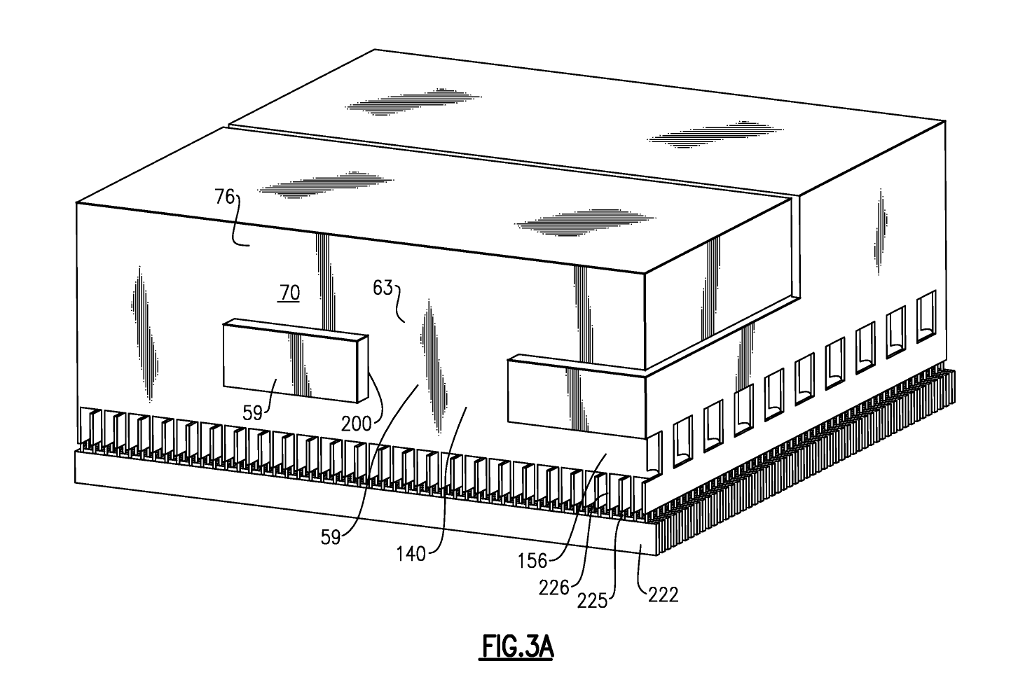

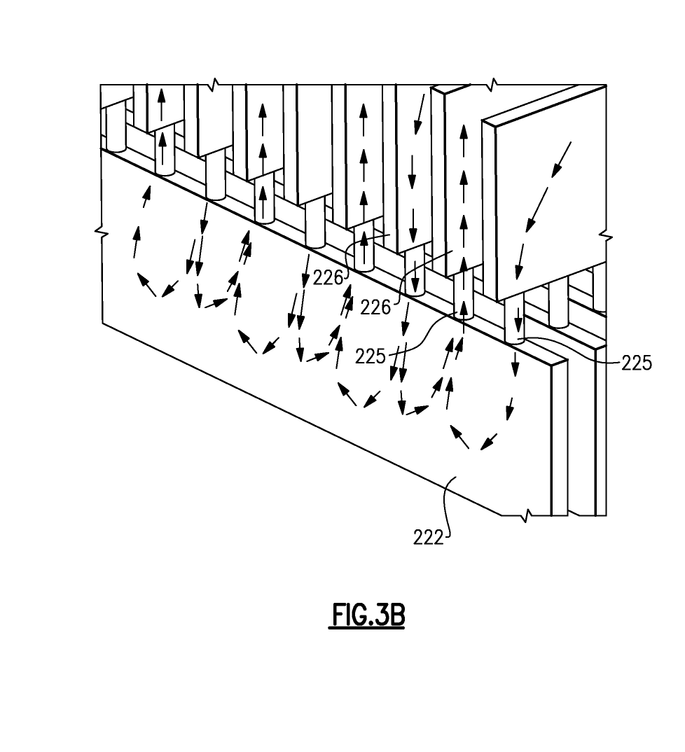

Thus, FIG. 2A shows an array 40 that provides a fluid cooler packet. The array 40 incorporates and cools a large number of the assemblies 20, such as shown in FIG. 1. In one embodiment, there may be a 10 by 10 array of the FIG. 1 assemblies 20 within the array 40. Of course, other numbers would come within the scope of this disclosure.

A supply port 42 and a discharge or return port 44 are shown. A cooling packet or circuit 141 associated with one of the assemblies 20 is shown in an exploded view. As shown, a supply 17 supplies cooling fluid into the supply port 42, and a downstream destination 15 receives return fluid from the return port 44. As shown schematically, a heat exchanger HE may be between the destination 15, and source 17 such that the cooling fluid is recirculated in a closed loop.

As shown in FIG. 2B, a silicone layer 46 is positioned adjacent the assembly 20.

An impingement channel layer 50 has a plurality of channels 251 extending generally parallel to each other.

As can be seen, the layer 50 has a higher density central area 47, with a higher density of channels 251, and a lower density outer area 49 with a lower density of channels 251. The lower density area 49 is associated with cooling the area 24 of component 22 while the area 47 is positioned to cool the higher heat area 26.

An orifice layer 52 includes a plurality of holes 51 in a higher density area 331, and other holes 153 in a lower density area 332.

A small slot layer 54 provides a number of supply and return slots 23 and has area 53 with a high density of slots 23 and area 55 of a lower density of slots 23. As can be appreciated, these areas are also associated with the area 26 and the area 24 on component 22, respectively.

As shown somewhat schematically in FIG. 2C, the small slot layer 54 has a channel 754 which communicates with a plurality of the slots 23 in the upper surface. It should be understood that spaced into the plane of this Figure, there would be other channels, which are maintained separate from channel 754, and alternate ones of the channels provide supply and return flow passages, as will be better described below.

A large slot layer 56 has slots 111 that communicate the slots 23 in the small slot layer 56 into a plurality of channels 59 in an outer channel layer 58. A porting layer 60 has openings 61, 62, 63 and 64. As can be seen, an opening 64 is associated with one channel 59. Ribs 159 within the layer 58 separate the channels 59, such that other openings 61, 63 and 64 are each associated with distinct channels 59.

As shown schematically in FIG. 2D, the slots 111 communicate with an elongated channel 756. Again, separate channels would be spaced into the plane of this Figure, and would also provide separate supply and return passages. In general, the slots and channels of the layer 54 and layer 56 extend perpendicular to each other.

A separator layer 66/69 has walls which will separate the flow from the openings 61 and 64 into a channel or passage 68 and the flow from ports 62 and 63 into a channel or passage 70. A header portion 72 has a closure wall 74 blocking flow from the channel 68 into a passage 76, but allowing flow from the channel 70 into the passage 76. Downstream of the header 72, there will be another header, which provides the reverse structure, and will communicate the channel 68 into another passage similar to passage 76.

As can be appreciated from FIG. 2B, a portion of the passage 76 communicates with a space 75 that would be above the wall 74, and channel or passage 68. As will be disclosed below, with regard to the overall header, this provides a “nested” arrangement for the header which more efficiently uses the overall space.

FIG. 2E shows the assembly of the various layers on to the assembly 20. If the channel 68 is a supply channel and the channel 70 is a return channel, then fluid would be supplied into the channel 68, pass through the opening 64 and 61 into channels 59 in the layer 58, and then through associated slots 111 in the layer 56, through slots 23 in the layer 54, holes 51/153 in layer 52, and into a channel 251 in layer 50.

The flow downstream of the orifices 51/153 in the layer 52 then impacts upon the electronic component 20 cooling it. The fluid passes along the channel 251 until moving back outwardly through other holes 51/153 in the orifice layer 54 that may be associated with slots 23 in the small slot layer 54, and associated with a slot 111 moving into a channels 159 that is associated with a return passage.

The fluid then passes through an opening 62/63 in porting layer 60 and into passage 76.

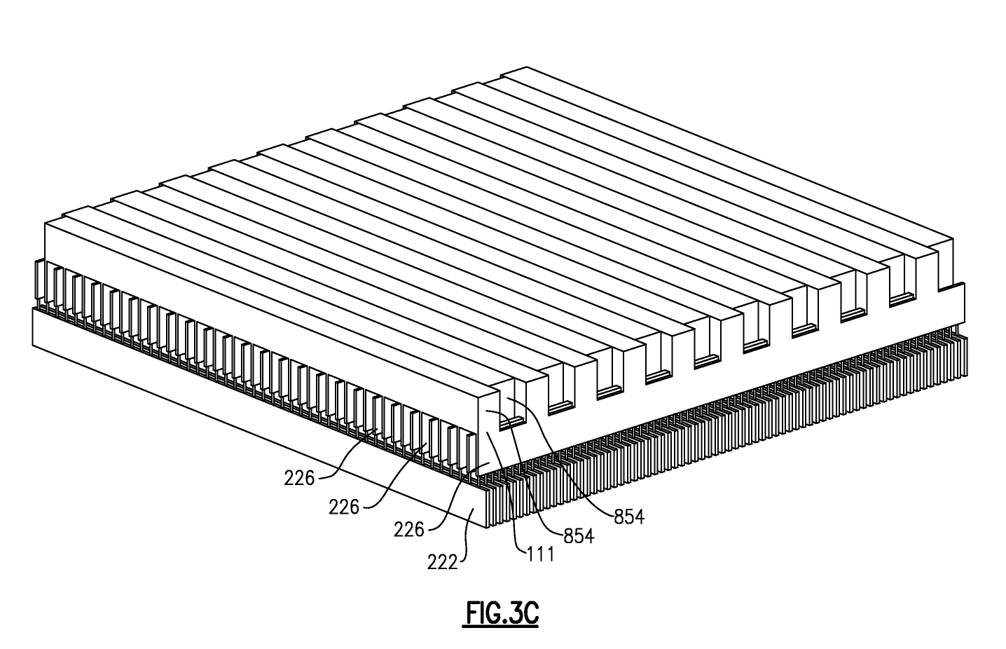

FIG. 3A shows the spaces within the layers of FIGS. 2B and 2C, rather than the structure of the layers. FIG. 3 is a “reverse” model from the structure illustrated in the earlier figures and shows the shape and size of the flow passages, rather than the structure that forms the flow passages. The lines separating areas in FIG. 3 would actually include structure, such as the walls and the layers as shown in the earlier figures.

FIG. 3A shows the combination of the channel 70 and passage 76 communicating with an opening 63 to in turn communicate with a channel 59. Another channel 59 is shown as being separated by a line 200. As mentioned above, the line 200 will actually be a structural wall in the cooling circuit as formed.

An area 140 would be an opening into one of the slots 111, and a portion 156 would be formed by the slots 111 within the body of the layer 56. Portions 226 are formed by the slots in the small slot layer 54. Pins 225 are formed by the holes in the orifice layer 52. The portions 222 are the actual impingement channels 51 within the impingement channel layer 50.

To this point, the disclosure has focused largely on cooling a single assembly 20. However, as mentioned above, the overall array of embodiment 40 may include a plurality of such assemblies.

FIG. 3B shows the impingement of the fluid coming through one orifice 225 into an impingement channel 222. FIG. 3B is also a “reverse” model showing the flow passages rather than structure. This flow then impacts upon the component to be cooled, flows along a channel, and then moves upwardly through an adjacent orifice 225 and communicates back through a return passage 226, which may be defined by the channel 754 in the small slot layer 54.

FIG. 3C shows the adjacent passages 226 formed by the channels 756 communicating through slots 111 to passages 854 which are formed by the channels 754 in the large slot layer 54. The slots 111 will then communicate these passages 754 along supply and return paths, as can be appreciated. FIG. 3C is also a “reverse” model.

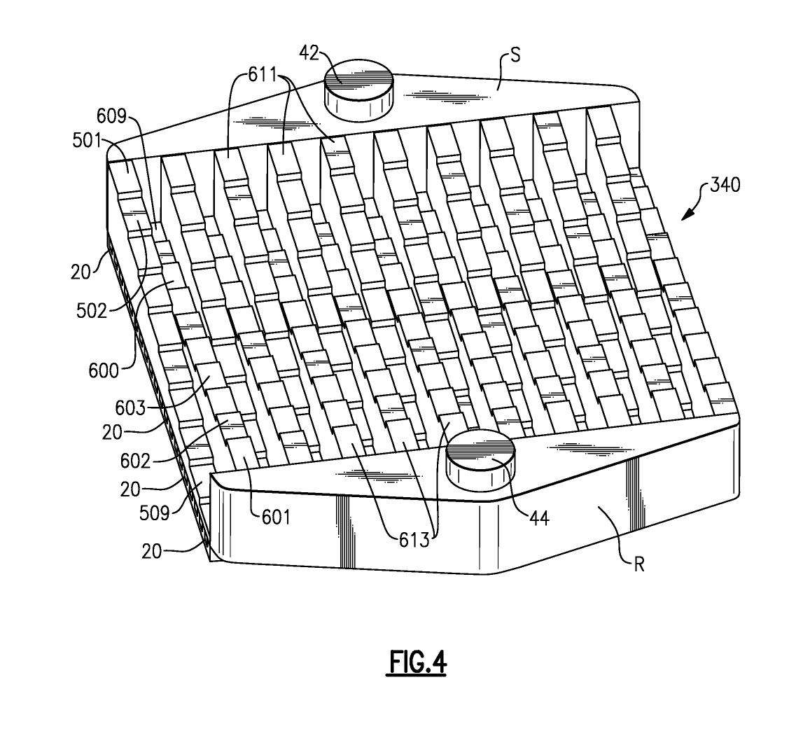

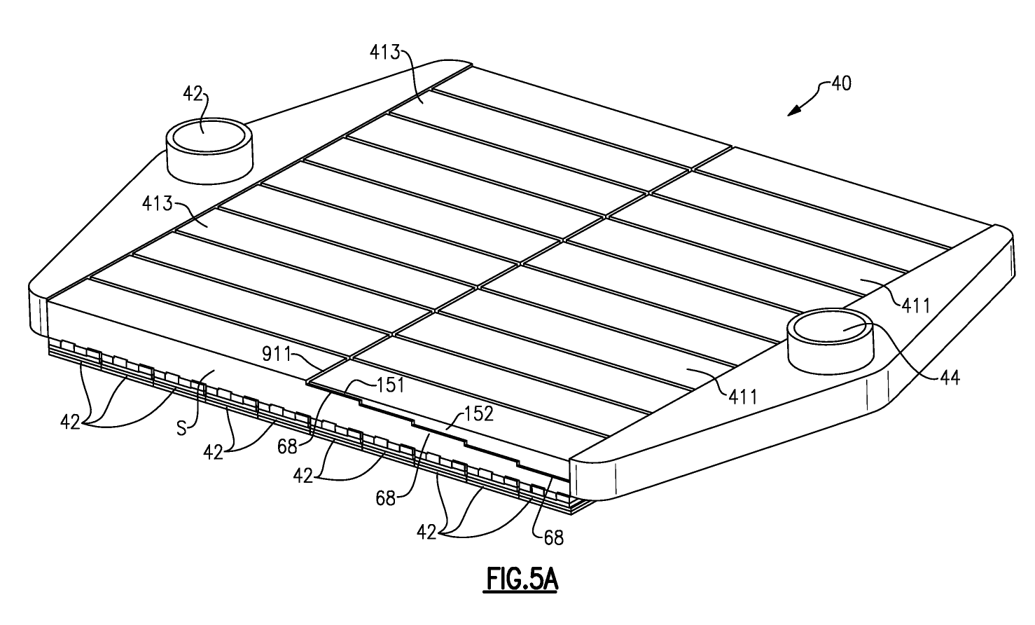

FIG. 4 shows a header structure for the array 40. As shown in FIG. 4, a supply header S and a return header R are positioned at opposed ends of an array 340. This is not the “nested” embodiment as mentioned above with regard to FIG. 2B, but rather an alternative.

Any other number of other arrangements can be utilized to communicate between the header and the component to be cooled.

There would be a greater amount of supply fluid at an upstream end of the supply port 42, and a smaller amount of return fluid at that most upstream point. As the supply header moves toward a downstream end, the volume of the supply fluid would decrease, while the volume of return fluid would increase. Thus, in embodiment 340, there is a “stepped” sizing to the headers, such that the return header has a smallest volume point 609, increasing through point 600, 603, 602, and eventually to point 601 which is relatively high.

On the other hand, the supply header has a highest volume 501 decreasing through steps 502, and eventually reaching a smallest point 509. By sizing the header flow volumes to increase or decrease as the volume could be handled by also increases or decreases, this header embodiment 340 will ensure that the pressure is maintained as desired along the entire flow path.

There are also a plurality of parallel supply header portions 611 and parallel return header portions 613. The supply header portions 611 decrease in size, and hence volume, in a downstream direction moving from the supply port 42 toward the return port 44. As illustrated there are a plurality of assemblies 20 associated with each of the steps, such that the parallel supply header portions 611 decrease in a stepped manner with each assembly 20 moving in a downstream direction. Similarly, the return header steps increase along each of the parallel return header portions 613. In one embodiment, the array 340 is a 10×10 array cooling 100 electronic components 22. Each step along each of the parallel supply and return header portions 611 and 613 would change by 10% from the prior step.

Of course, if there were a number other than 10 of the steps, the change would not be 10%. However, in some embodiments, the change is generally equal for each step. As an example, if there were four steps, the change might be 25% on each step, in one embodiment.

It could be said that the assemblies 20 are formed into columns and rows, with the rows each being associated with one of the parallel supply header portions 611, and one of the parallel return header portions 613. Each step along each of the portions 611/613 is associated with one of the columns across the rows.

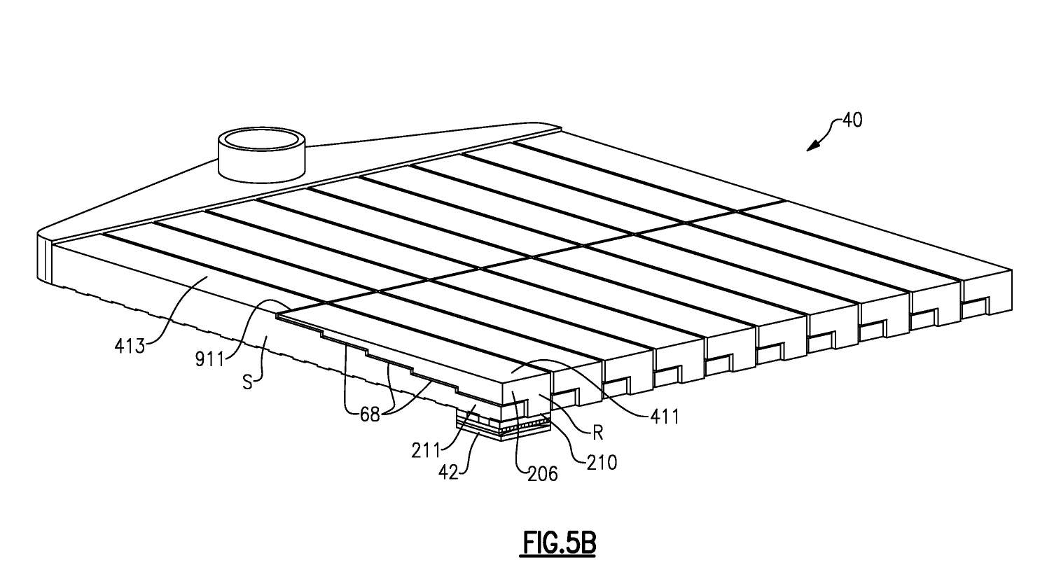

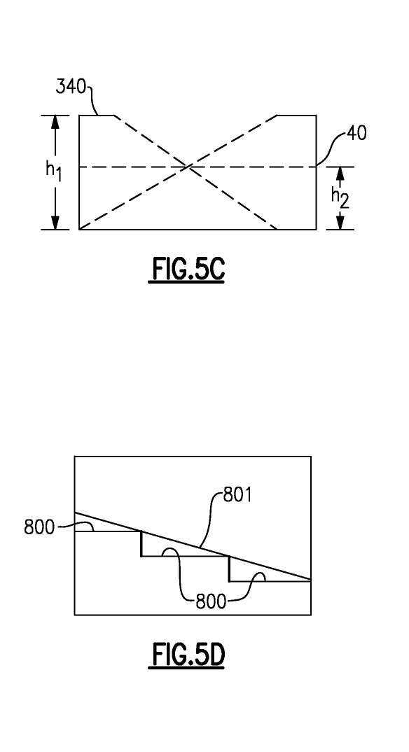

FIG. 5A shows a header embodiment 140. Header embodiment 140 more efficiently utilizes a space (see 65 in FIG. 2B, as an example) which is above the steps of the header embodiment 340, and results in a more compact overall array 40. This nested embodiment is what is illustrated in FIG. 2B. As can be appreciated, the supply header S has its portions shown to the bottom right hand side of FIG. 5A which actually communicate the cooling fluid and decrease in size as shown at 68. These are also nested return header portions 151, 152, etc. above the supply header portions.

Thus, the unused space beyond the stepped header portions of the FIG. 4 embodiment 340 are now utilized to provide some of the flow volume.

As seen in FIG. 5B, which is again a reverse model, the supply header communicates to cool an assembly through a cooling circuit and as shown at 211. There are decreasing channel steps 68, which are provided by the structure shown at 142, 146, 147, etc. in FIG. 5A. However, there is a nested portion 206 of the return header R which extends outwardly, or on a reverse face of supply headers facing away from the component and cooling circuits 42. This nested portion is formed for example by the area or space 75 as shown in FIG. 2B. A portion 210 of the return header R also communicates with a cooling circuit 42, and would for example be the channel 76 as shown in FIG. 2B.

Again, there would be associated rows and columns, and associated parallel supply header portions 413, and associated parallel return header portions 411.

As shown in FIGS. 5A and 5B, there is a breakpoint 911 between an upper surface of the supply header portions 413, and an upper surface of the return header portions 411. In the first half of the “steps,” there would be a nested portion on the supply header above the return header. In a second half, the nested portion are as illustrated in FIGS. 5A and 5B, as being part of the return header, and being outwardly of the supply header step portions. This switch in the headers that have the nested portion is necessary, as the nested portion must be able to communicate with the portion actually supplying the fluid to the components in the supply header, and able to communicate back into the return header from those components. Thus, it is only some of the plurality of cooling circuits which have the nested portions on the return header and the nested portions on the supply header.

With the embodiment 40 as illustrated in FIGS. 5A and 5B, there is a reduction in height as is illustrated in FIG. 5C. The embodiment 340 would require a height h₁ due to the unused space. The embodiment 40 however would have a much smaller height h₂, while maintaining the same flow vs pressure drop performance, due to the nested combination.

The header embodiments illustrated in this invention provide improved pressure regulation along the path of both the supply and return fluids. It should be understood that all of the flow passages illustrated in this disclosure can be formed by silicon layering techniques.

Further, while the increase and decrease in the headers is shown in a step fashion, in embodiments, they may generally be more ramped, and formed along a single slope. Thus, as shown in FIG. 5D, rather than the steps shown at 800, one embodiment would actually extend along a slope shown at 801.

Although an embodiment of this invention has been disclosed, a worker of ordinary skill in this art would recognize that certain modifications would come within the scope of this disclosure. For that reason, the following claims should be studied to determine the true scope and content of this disclosure.

1. A fluid cooler packet for a plurality of electronic components comprising:
a plurality of individual cooling circuits for receiving a supply of cooling fluid from a supply header and delivering that cooling fluid to an associated electronic component, said plurality of cooling circuits each including a return passage for receiving a return fluid after having cooled the associated electronic component, and returning the return fluid to a return header; and
a volume of the supply header decreasing in a downstream direction as it passes over the plurality of individual cooling circuits, and a volume of the return header increasing as it moves in a downstream direction over the plurality of individual cooling circuits.

2. The packet as set forth in claim 1, wherein said plurality of individual cooling circuits are assembled in an array of rows and columns, and there are a plurality of parallel supply header portions associated with each of said rows, and a plurality of parallel return header portions associated with each of said rows, with a downstream direction being defined across said plurality of columns.

3. The packet as set forth in claim 2, wherein said plurality of parallel supply header portions decrease in steps across each of said plurality of individual cooling circuits, and said plurality of parallel return header portions increasing in steps across each of said plurality of individual cooling circuits.

4. The packet as set forth in claim 3, wherein a supply port communicates with said supply header at one end of said fluid cooler, and a return port positioned at an opposed end relative to the supply port communicates with said return header.

5. The packet as set forth in claim 4, wherein said parallel supply header portions have nested portions which are positioned outwardly of a face of said parallel return header portions spaced away from at least some of the individual cooling circuits, with a volume of said nested portions of said parallel supply header portions decreasing as said volume of said return header parallel portions increases in a downstream direction, and said parallel return header portions have nested portions which are positioned outwardly of a face of said parallel supply header portions spaced away from at least some of the individual cooling circuits, with a volume of said nested portions of said parallel return header portions increasing as said volume of said supply header parallel portions decreases in a downstream direction.

6. The packet as set forth in claim 3, wherein said parallel supply header portions have nested portions which are positioned outwardly of a face of said parallel return header portions spaced away from at least some of the individual cooling circuits, with a volume of said nested portions of said parallel supply header portions decreasing as said volume of said return header parallel portions increases in a downstream direction, and said parallel return header portions have nested portions which are positioned outwardly of a face of said parallel supply header portions spaced away from at least some of the individual cooling circuits, with a volume of said nested portions of said parallel return header portions increasing as said volume of said supply header parallel portions decreases in a downstream direction.

7. The packet as set forth in claim 1, wherein said return header having a nested portion associated with a face of said supply header facing away from at least some of the plurality of cooling circuits, and said nested portion of said return header increasing in volume as the volume of said supply header decreases in a downstream direction, and said supply header having a nested portion outwardly of a face of said return header facing away from at least some of the plurality of individual cooling circuits, with said nested portion of said supply header decreasing in volume as said return header increases in volume along a downstream direction.

8. The packet as set forth in claim 7, wherein walls isolating said nested portions, with said walls being outwardly of return and supply channel portions to separate return and supply fluid flows.

9. The packet as set forth in claim 1, wherein the individual cooling circuits include an impingement channel layer for directing fluid against an electronic component, and communicating that fluid back through into said return header.

10. The packet as set forth in claim 9, wherein an orifice layer is positioned outwardly of the impingement channel layer, with said orifice layer having a plurality of holes, with sets of said holes communicating with a return channel portion, and other of said holes communicating with a supply channel portion, with said return and supply channels communicating back into said return and supply headers, respectively.

11. An electronic component array comprising:
a plurality of electronic components; and
a fluid cooling packet having a plurality of individual cooling circuits for receiving a supply of cooling fluid and each delivering that cooling fluid to an associated one of said plurality of electronic components, and said plurality of cooling circuits each including a return passage for receiving a return fluid after having cooled each of the plurality of associated components, and returning the return fluid to a return header, a volume of the supply header decreasing in a downstream direction as it passes over the plurality of individual cooling circuits, and a volume of the return header increasing as it moves in a downstream direction over the plurality of individual cooling circuits.

12. The array as set forth in claim 11, wherein said plurality of individual cooling circuits are assembled in an array of rows and columns, and there are a plurality of parallel supply header portions associated with each of said rows, and a plurality of parallel return header portions associated with each of said rows, with a downstream direction being defined across said plurality of columns.

13. The array as set forth in claim 12, wherein said plurality of parallel supply header portions decrease in steps across each of said plurality of individual cooling circuits, and said plurality of parallel return header portions increasing in steps across each of said plurality of individual cooling circuits.

14. The array as set forth in claim 13, wherein a supply port communicates with said supply header at one end of said fluid cooler, and a return port positioned at an opposed end relative to the supply port communicates with said return header.

15. The array as set forth in claim 14, wherein said parallel supply header portions have nested portions which are positioned outwardly of a face of said parallel return header portions spaced away from at least some of the individual cooling circuits, with a volume of said nested portions of said parallel supply header portions decreasing as said volume of said return header parallel portions increases in a downstream direction, and said parallel return header portions have nested portions which are positioned outwardly of a face of said parallel supply header portions spaced away from at least some of the individual cooling circuits, with a volume of said nested portions of said parallel return header portions increasing as said volume of said supply header parallel portions decreases in a downstream direction.

16. The array as set forth in claim 13, wherein said parallel supply header portions have nested portions which are positioned outwardly of a face of said parallel return header portions spaced away from at least some of the individual cooling circuits, with a volume of said nested portions of said parallel supply header portions decreasing as said volume of said return header parallel portions increases in a downstream direction, and said parallel return header portions have nested portions which are positioned outwardly of a face of said parallel supply header portions spaced away from at least some of the individual cooling circuits, with a volume of said nested portions of said parallel return header portions increasing as said volume of said supply header parallel portions decreases in a downstream direction.

17. The array as set forth in claim 11, wherein said return header having a nested portion associated with a face of said supply header facing away from at least some of the plurality of cooling circuits, and said nested portion of said return header increasing in volume as the volume of said supply header decreases in a downstream direction, and said supply header having a nested portion outwardly of a face of said return header facing away from at least some of the plurality of individual cooling circuits, with said nested portion of said supply header decreasing in volume as said return header increases in volume along a downstream direction.

18. The array as set forth in claim 17, wherein walls isolating said nested portions, with said walls being outwardly of return and supply channel portions to separate return and supply fluid flows.

19. The array as set forth in claim 11, wherein the individual cooling circuits include an impingement channel layer for directing fluid against an electronic component, and communicating that fluid back through into said return header.

20. The array as set forth in claim 19, wherein an orifice layer is positioned outwardly of the impingement channel layer, with said orifice layer having a plurality of holes, with sets of said holes communicating with a return channel portion, and other of said holes communicating with a supply channel portion, with said return and supply channels communicating back into said return and supply headers, respectively.
